(19) United States
(12) Patent Application Publication
(10) Pub. No.: US 2006/0125020 A1
(43) Pub. Date: Jun. 15, 2006

(54) CMOS image sensor and method for fabricating the same

(76) Inventor: Meng An Jung, Bumseong-gun (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(21) Appl. No.: 11/303,188

(22) Filed: Dec. 15, 2005

(30) Foreign Application Priority Data
Dec. 15, 2004 (KR) 10-2004-0105954

(51) Int. Cl. H01L 29/94

(52) U.S. Cl. 257/369

(57) ABSTRACT

A CMOS image sensor and a method for fabricating the same are disclosed, in which an incidence of void formation is reduced or prevented, to improve characteristics of the image sensor. The CMOS image sensor includes a plurality of photodiode areas in a semiconductor substrate at constant intervals, a dielectric layer on or over the semiconductor substrate and the photodiode areas, a color filter layer on or over the dielectric layer at constant intervals, a void prevention layer between adjacent color filters in the color filter layer, a planarization layer on or over the semiconductor substrate and the void prevention layer, and a plurality of microlenses on the planarization layer.

This application claims the benefit of the Korean Patent Application No. P2004-105954, filed on Dec. 15, 2004, which is hereby incorporated by reference as if fully set forth herein.

### BACKGROUND OF THE INVENTION

1. Field of the Invention

The present invention relates to an image sensor, and more particularly, a complementary metal-oxide semiconductor (CMOS) image sensor and a method for fabricating the same that reduces or prevents the incidence of a void that may be formed between respective color filter layers, to improve characteristics of the image sensor.

2. Discussion of the Related Art

Generally, an image sensor is a semiconductor device that converts optical images to electrical signals. The image sensor includes a charge coupled device (CCD) image sensor and a CMOS image sensor.

The CMOS image sensor includes a photodiode area configured to sense light and a CMOS logic circuit area configured to process the sensed light to generate electrical signals. If the light-receiving capability of the photodiode is great, the image sensor may be considered to have excellent photosensitivity characteristics.

To enhance photosensitivity, one may increase a fill factor (e.g., a ratio of an area occupied by the photodiode relative to the whole area of the image sensor). Alternatively, one may change a path of incident light on an area other than the photodiode so as to converge light to the photodiode.

To converge light to the photodiode, a microlens is generally used. A convex microlens made of material having good light transmittance may be formed on or over the photodiode to refract a path of incident light, thereby irradiating or transmitting more light to the photodiode. In this case, for example, light parallel to a light axis of the microlens may be refracted by the microlens so that a focal point is formed on or at a certain position of the light axis.

Hereinafter, a related art CMOS image sensor will be described with reference to the accompanying drawings.

FIG. 1 is a sectional view illustrating a related art CMOS image sensor.

As shown in FIG. 1, a plurality of photodiode areas 20 are formed in a semiconductor substrate 10 at constant intervals to generate charges in response to incident light. A light-shielding layer 30 may be formed on the semiconductor substrate 10 between the photodiode areas 20 to prevent light from entering an area other than the photodiode areas 20. A dielectric interlayer 40 is formed on the entire surface of the semiconductor substrate 10 including the light-shielding layer 30. Color filter layers 50, for example of red (R), green (G) and blue (B), may be formed on the dielectric interlayer 40 at constant intervals to respectively pass through light of specific wavelengths. A planarization layer 60 may be formed on the entire surface of the semiconductor substrate 10 including the color filter layers 50. A convex microlens 70 having a certain curvature may be formed on the planarization layer 60 to pass light through a corresponding one of the color filter layers 50, thereby converging light to the photodiode areas 20.

The CMOS image sensor may include a photogate type sensor, as opposed to a photodiode type sensor, for sensing light. Each of the R, G and B color filter layers 50 is generally formed by a photo-etching process using a separate mask for each color after depositing a corresponding photosensitive material. Also, the R, G and B color filter layers may be formed at constant intervals. Furthermore, the curvature and the height of the microlens 70 may be determined after considering various factors such as a focal point of converged light. A photoresist is generally used as the microlens 70. The microlens 70 is generally formed by deposition, patterning and reflow processes.

FIG. 2 is a plan view illustrating color filter layers in the related art CMOS image sensor.

As shown in FIG. 2, the color filters may comprise a 2×2 array containing two pixels of a first color (e.g., green), one pixel of a second color (e.g., blue), and one pixel of a third color (e.g., red). Neighboring 2×2 pixel arrays may contain two pixels of a different color (e.g., blue or red), and one pixel of each of the remaining colors (e.g., green and the other of blue or red, depending on which color is used for the two pixels). A photoresist having each color is coated using a photolithographic process and then respective pixels are sequentially formed.

However, since the color filter layers are generally formed at constant intervals, a void 80 may be formed between the respective color filters.

As described above, the related art CMOS image sensor has the following problems.

When the photodiode receives light, an error in operation of the photodiode may be caused because of the void formed between the respective color filters. This can deteriorate certain characteristics of the image sensor.

### SUMMARY OF THE INVENTION

Accordingly, the present invention is directed to a CMOS image sensor and a method for fabricating the same that substantially obviates one or more problems due to limitations and/or disadvantages of the related art.

An object of the present invention is to provide a CMOS image sensor and a method for fabricating the same in which an incidence of a void being formed between adjacent color filter layers may be reduced or prevented, to thereby improve characteristics of the image sensor.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) and/or method(s) particularly pointed out in the written description and claims hereof as well as the appended drawings.

To achieve these objects and other advantages and in accordance with the purpose of the invention, as embodied and broadly described herein, a CMOS image sensor according to the present invention includes a plurality of photodiode areas in a semiconductor substrate at substantially constant intervals, a dielectric layer on an entire surface of the active area of the semiconductor substrate including the photodiode areas, a plurality of color filters on or over the dielectric layer at substantially constant intervals, a void prevention layer between adjacent color filters and (optionally) on a peripheral part of the color filters, a planarization layer on or over the semiconductor substrate including the void prevention layer, and a plurality of microlenses on the planarization layer, corresponding to respective color filters.

In another aspect of the present invention, a method for fabricating a CMOS image sensor includes forming a dielectric layer on a semiconductor substrate that includes a plurality of photodiode areas, forming a plurality of color filters on or over the dielectric layer at substantially constant intervals, forming a void prevention layer between adjacent color filters and (optionally) on a peripheral part of the color filters, forming a planarization layer on or over the semiconductor substrate including the void prevention layer, and forming a plurality of microlenses on the planarization layer, corresponding to the respective color filters.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view of a related art CMOS image sensor;

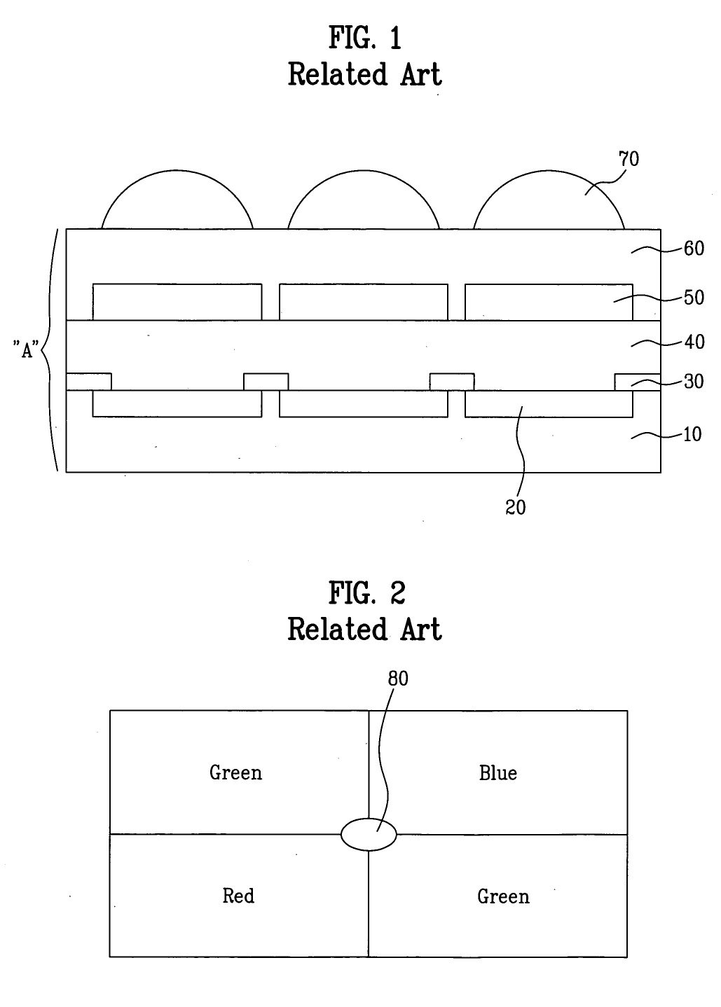

FIG. 2 is a plan view illustrating color filters in the related art CMOS image sensor;

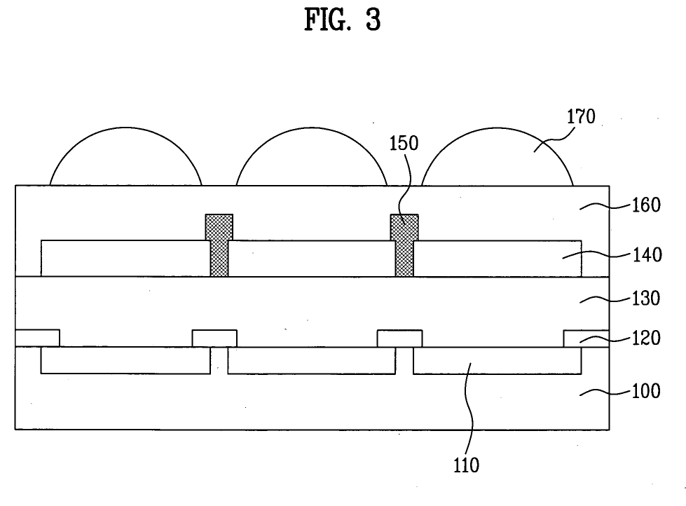

FIG. 3 is a cross-sectional view of a CMOS image sensor according to an embodiment of the present invention; and

FIG. 4A to FIG. 4D are cross-sectional views illustrating process steps for fabricating a CMOS image sensor according to an embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

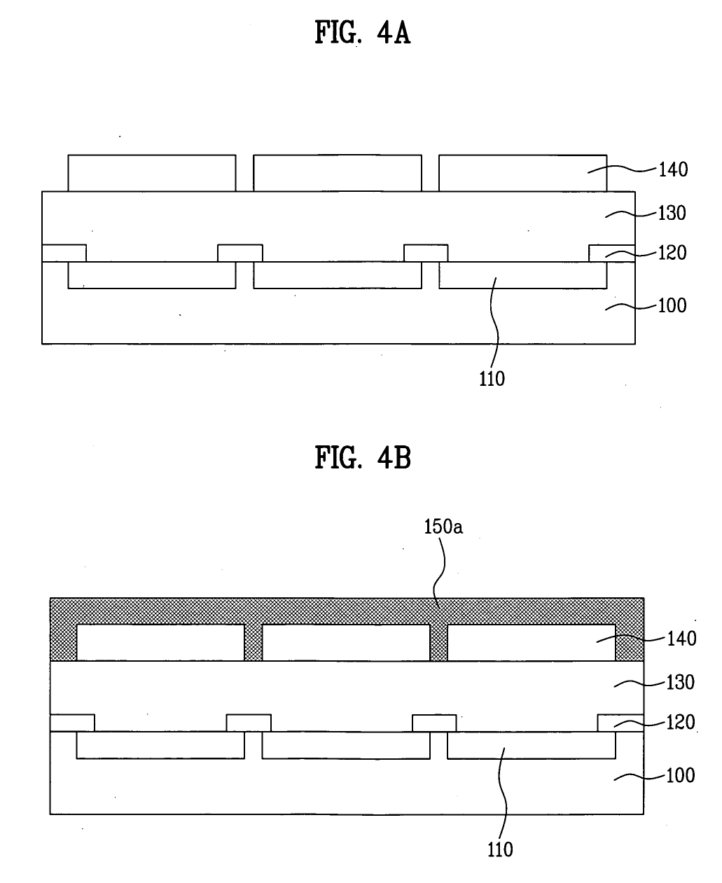

FIG. 3 is a cross-sectional view of a CMOS image sensor according to an embodiment of the present invention.

As shown in FIG. 3, the CMOS image sensor according to the present invention includes a plurality of photodiode areas 110 in a semiconductor substrate 100 at substantially constant intervals. In general, each of the photodiode areas 110 is configured to generate electrical charges (generally resulting in an electrical signal) in response to incident light being received thereon.

The present CMOS image sensor may further include a light-shielding layer 120 on peripheral portions of the photodiode areas 110 and on the semiconductor substrate 100 between the photodiode areas 110. In general, the light-shielding layer 120 is configured to prevent light from entering an area other than the photodiode areas 110. The present CMOS image sensor may further include a dielectric layer 130 generally on the entire surface of the semiconductor substrate 100, including the light-shielding layer 120. In some cases, dielectric layer 130 may be considered to be a dielectric “interlayer” because it is located between substrate 100 and an overlying functional layer (e.g., color filter layer 140). Generally, dielectric layer 130 comprises an oxide, nitride or oxynitride of silicon and/or aluminum (typically, silicon dioxide).

The present CMOS image sensor further comprises a color filter layer 140, comprising a plurality of individual color filters, generally in an n-by-m array (where n and m are independently an integer of from 8, 16, 32, 64 or 128 to 64, 128, 256, 1024, 2048, 4096 or more). In one example, the color filters comprise red (R), green (G) and blue (B) filters on the dielectric layer 130 at substantially constant intervals. In another example, the color filters comprise yellow (Y), magenta (M) and cyan (C) filters. The color filters of layer 140 are generally configured to respectively pass through light of a specific wavelength or wavelength band to an underlying photodiode area 110. Also, while the individual color filters may have different thicknesses, the color filter layer is generally formed on a common horizontal structure (e.g., each color filter has a lower surface in contact with a common underlying surface).

An important aspect of the present invention involves a void prevention layer 150 is between adjacent color filters in color filter layer 140 and (optionally) on the peripheral portion of the color filters in color filter layer 140. In one embodiment, the void prevention layer 150 is only between adjacent color filters 140. In another embodiment, the void prevention layer 150 is on a peripheral portion of no greater than the outermost 10% of the color filters. In a further embodiment, the peripheral portion of the color filter on which the void prevention layer 150 lies is defined by the photolithographic alignment tolerance of the void prevention layer 150 formation step. Generally, the void prevention layer 150 will overlie a peripheral portion of the color filter of from about zero to about two alignment tolerances in width. To the extent the void prevention layer 150 has an upper surface substantially above the upper surface of the color filter layer 140, the void prevention layer 150 may also provide a light-shielding function similar to that provided by light-shielding layer 120. Thus, the void prevention layer 150 may have an upper surface from 3000 to 10,000 Å above the upper surface of the color filter layer 140.

The present CMOS image sensor may further comprise a planarization layer 160 on or over the entire surface of the active area of semiconductor substrate 100, including the void prevention layer 150. Furthermore, the exemplary CMOS image sensor includes a plurality of convex microlenses 170, generally having a certain or predetermined curvature, on the planarization layer 160. Each microlens 170 is configured to pass light through to and/or focus or converge light on a corresponding (and generally underlying) one of the color filters in layer 140, thereby further converging light to or focusing light on a corresponding (and generally underlying) the photodiode areas 110.

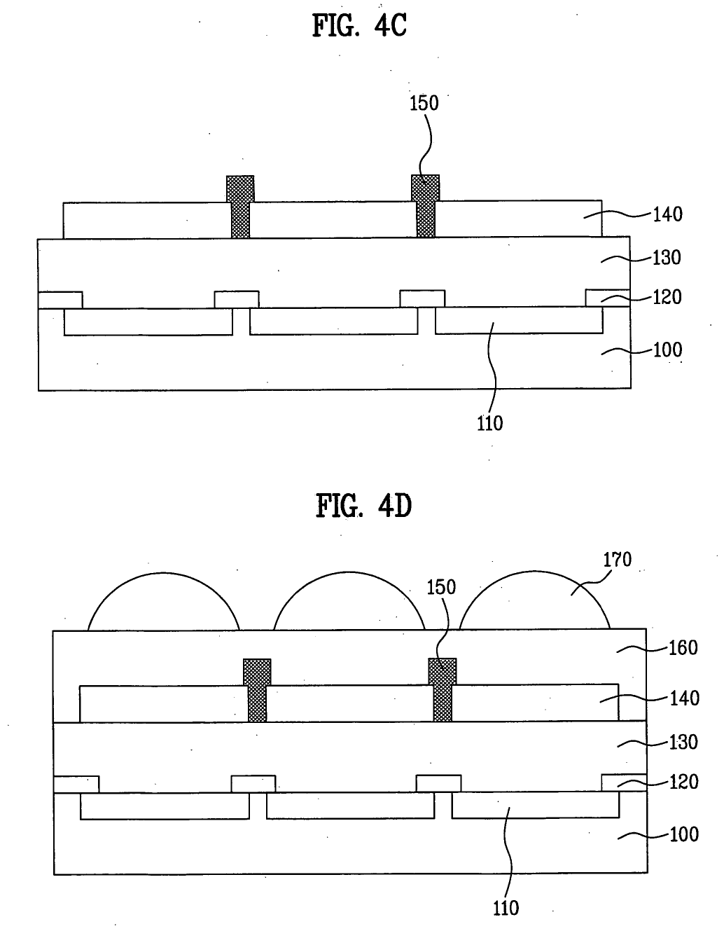

FIG. 4A to FIG. 4D are cross-sectional views illustrating process steps of fabricating a CMOS image sensor according to an embodiment of the present invention.

As shown in FIG. 4A, a plurality of photodiode areas 110 are formed in a semiconductor substrate 100 at substantially constant intervals, and an opaque metal film (such as Cr) is deposited on the entire surface of the semiconductor substrate 100, including the photodiode areas 110.

Subsequently, the opaque metal film is patterned by photolithographic and selective etching processes to remain only on the semiconductor substrate 100 between the photodiode areas 110 (and, to some extent, on the peripheral portions of the photodiode areas 110), so as to form a light-shielding layer 120.

A dielectric layer 130 is then formed on the entire surface of the semiconductor substrate 100, including the light-shielding layer 120. Typically, the dielectric layer 130 comprises an insulator material that is substantially transparent to visible light, such as silicon dioxide, silicon nitride and/or aluminum oxide. Also, the light-shielding layer 120 may comprise multiple layers.

Next, a photoresist (e.g., a salt resist) is deposited on the dielectric layer 130 and then patterned by exposing and selective developing processes to form a first subset of color filters (e.g., red, green or blue filters) in color filter layer 140 at substantially constant intervals. The other color filters (e.g., other than the first subset of color filters), which filter light at their respective wavelengths, may be subsequently formed by a substantially similar process in independent color filter formation processes.

As shown in FIG. 4B, a black photoresist 150a is deposited on the entire surface of the semiconductor substrate 100, including the color filter layers 140. Then, as shown in FIG. 4C, the black photoresist 150a is patterned by exposing and selective developing processes to remain only between adjacent color filters in layer 140 and on the peripheral areas of the color filters in layer 140, thereby forming a void prevention layer 150. Alternatively, the black photoresist 150a may be etched back to remove substantially all of the photoresist 150a from over the color filters 140, but leave photoresist 150a between adjacent color filters 140.

As shown in FIG. 4D, a planarization layer 160 is formed on or over the entire surface of the active area of the semiconductor substrate 100, including the void prevention layer 150. Afterwards, a material layer for microlens (generally a photoresist having a reflow or melting temperature lower than that of the color filter layer 140) is deposited on the planarization layer 160 and then patterned by exposing and developing processes to form a microlens pattern. Alternatively, an oxide film such as TEOS may be used as the material layer for the microlens bodies.

Subsequently, a microlens 170 may be formed by reflowing the microlens pattern (e.g., the microlens bodies). The reflow process may be performed using a hot plate or furnace. The curvature of the microlens 170 may depend on the contracting and heating methods applied to the microlens bodies, and the convergence efficiency of the microlens 170 depends on the curvature.

The microlens 170 is hardened by irradiating ultraviolet rays. In this case, the microlens 170 can have an optimal curvature radius.

As described above, the CMOS image sensor and the method for fabricating the same according to the present invention have the following advantages.

Since a void prevention layer may be formed between adjacent color filters, erroneous operations of the photodiode may be reduced or avoided, thereby improving characteristics of the image sensor. Further, the light-sensing capability and/or light detection accuracy of the image sensor may also improve as a result of the present invention (e.g., an enhanced light-shielding capability).

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A CMOS image sensor comprising:
a plurality of photodiode areas in a semiconductor substrate at substantially constant intervals;
a dielectric layer on or over an entire active area surface of the semiconductor substrate including the photodiode areas;
a color filter layer comprising a plurality of color filters on or over the dielectric layer at substantially constant intervals;
a void prevention layer between adjacent color filters and (optionally) on a peripheral part of the color filters;
a planarization layer on or over the entire surface of the semiconductor substrate active area, including the void prevention layer; and
a plurality of microlenses on the planarization layer, corresponding to the plurality of color filters.

2. The CMOS image sensor according to claim 1, wherein the void prevention layer comprises a black photoresist.

3. The CMOS image sensor according to claim 1, further comprising a light-shielding layer between adjacent photodiode areas, configured to prevent light from entering an area other than the photodiode areas.

4. The CMOS image sensor according to claim 1, wherein the color filters comprise red, green and blue filters.

5. The CMOS image sensor according to claim 1, wherein the color filter layer comprises an array of color filters.

6. The CMOS image sensor according to claim 1, wherein the void prevention layer is between each color filter and every color filter adjacent thereto.

7. The CMOS image sensor according to claim 1, wherein the peripheral part of the color filters includes no more than an outermost 10% of a color filter area.

8. The CMOS image sensor according to claim 7, wherein the peripheral part of the color filters has a width of zero to about twice an alignment tolerance.

9. The CMOS image sensor according to claim 1, wherein the void prevention layer has an upper surface above an outer surface of the color filter layer.

10. The CMOS image sensor according to claim 9, wherein the upper surface of the void prevention layer is from 3000 Å to 10,000 Å above the outer surface of the color filter layer.

11. A method for fabricating a CMOS image sensor comprising:
forming a dielectric layer on a semiconductor substrate comprising a plurality of photodiode areas;
forming a plurality of color filters on the dielectric layer at substantially constant intervals;
forming a void prevention layer between adjacent color filters and (optionally) on peripheral portions of the color filters;
forming a planarization layer on or over an entire active area surface of the semiconductor substrate, including the void prevention layer; and
forming a plurality of microlenses on or over the planarization layer corresponding to the plurality of color filters.

12. The method according to claim 11, wherein forming the void prevention layer comprises (i) depositing a black photoresist on the entire surface of the semiconductor substrate including the color filters and (ii) patterning the black photoresist using exposing and developing processes.

13. The method according to claim 11, further comprising forming a light-shielding layer between adjacent photodiode areas to prevent light from entering an area other than the photodiode areas.

14. The method according to claim 11, wherein the color filters comprise red, green and blue filters.

15. The method according to claim 11, wherein the color filter layer comprises an array of color filters.

16. The method according to claim 11, wherein the void prevention layer is between each color filter and every color filter adjacent thereto.

17. The method according to claim 11, wherein the peripheral part of the color filters includes no more than an outermost 10% of a color filter area.

18. The method according to claim 17, wherein the peripheral part of the color filters has a width of from zero to about twice an alignment tolerance.

19. The method according to claim 11, wherein the void prevention layer has an upper surface above an outer surface of the color filter layer.

20. The method according to claim 19, wherein the upper surface of the void prevention layer is from 3000 Å to 10,000 Å above the outer surface of the color filter layer.
